(19) United States
(12) Patent Application Publication
(10) Pub. No.: US 2025/0157915 A1
(43) Pub. Date: May 15, 2025

(54) STRUCTURES INCLUDING TRENCH CAPACITORS AND METHODS OF FORMING THE SAME

(71) Applicant: GlobalFoundries Singapore Pte. Ltd., Singapore (SG)

(72) Inventor: ANTHONY JEREMY VILLALON, Singapore (SG)

(21) Appl. No.: 18/510,621

(22) Filed: Nov. 15, 2023

(51) Int. Cl. H01L 23/522; H01L 21/762; H01L 23/00; H01L 23/528; H01L 23/58; H01L 23/64

(52) U.S. Cl. CPC H01L 23/5226; H01L 21/76224; H01L 23/528; H01L 23/585; H01L 23/642; H01L 24/08; H01L 2224/08145

(57) ABSTRACT

A structure including a first chip and a second chip stacked over and bonded to the first chip at a bonding interface is provided. The first and second chips form a device stack. The first chip includes a first dielectric and first interconnects arranged in the first dielectric. The second chip includes a second dielectric over the first dielectric and second interconnects arranged in the second dielectric. A trench capacitor is arranged in the device stack. The trench capacitor extends through the second chip, the bonding interface and at least partially into the first chip.

### TECHNICAL FIELD

The present disclosure relates generally to integrated circuits, and more particularly to structures including trench capacitors and methods of forming structures including trench capacitors.

### BACKGROUND

As electronic components have become smaller, more of them can be integrated onto a single chip. Alongside transistors and other active components, passive components such as resistors, capacitors, and inductors are being integrated in semiconductor devices. The integration of passive components has played a role in expanding the capabilities of integrated circuits (ICs), enabling the development of more efficient and versatile electronic systems. For example, the integration of capacitors into ICs has enabled the development of DC-DC converters such as in Radio Frequency (RF) circuits, decoupling circuitry, etc. The performance of the capacitors may be increased, for example, by integrating more of the capacitors into the circuitry, however, this may use up more of the footprint of the IC, which may otherwise be used for other devices (e.g., transistors) or functionalities. Accordingly, it is desirable to provide improved structures including capacitors and methods of forming thereof.

### SUMMARY

According to various embodiments, a structure including a first chip and a second chip stacked over and bonded to the first chip at a bonding interface is provided. The first and second chips form a device stack. The first chip includes a first dielectric and first interconnects arranged in the first dielectric. The second chip includes a second dielectric over the first dielectric and second interconnects arranged in the second dielectric. A trench capacitor is arranged in the device stack. The trench capacitor extends through the second chip, the bonding interface and at least partially into the first chip.

According to another aspect, a structure including a first chip and a second chip stacked over the first chip to form a device stack is provided. The first chip includes a first dielectric over a first active layer and first interconnects arranged in the first dielectric. The second chip includes a second dielectric over the first dielectric, and a second active layer over the second dielectric. Second interconnects are arranged in the second dielectric. A trench capacitor extends from a top side of the device stack through the second dielectric of the second chip and at least partially into the first dielectric of the first chip.

According to various embodiments, a method of forming a structure is provided. The method may include forming a first chip including a first dielectric and first interconnects arranged in the first dielectric, and a second chip including a second dielectric and second interconnects arranged in the second dielectric. The method may include stacking the second chip over the first chip with the second dielectric facing the first dielectric to form a device stack, and bonding the first chip and the second chip together. A trench capacitor is formed in the device stack. The trench capacitor extends through the second chip and at least partially into the first chip.

These and other advantages and features of the embodiments herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following:

FIG. 1 illustrates a cross-sectional view of an embodiment of a structure;

FIG. 2 illustrates a cross-sectional view of another embodiment of a structure;

FIG. 3 illustrates a cross-sectional view of yet another embodiment of a structure; and

FIGS. 4A-4D show cross-sectional views of a process for forming a structure.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the embodiments. Other embodiments may be utilized and structural, logical, and electrical changes may be made without departing from the scope of the invention. The various embodiments are not necessarily mutually exclusive, as some embodiments can be combined with one or more other embodiments to form new embodiments.

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

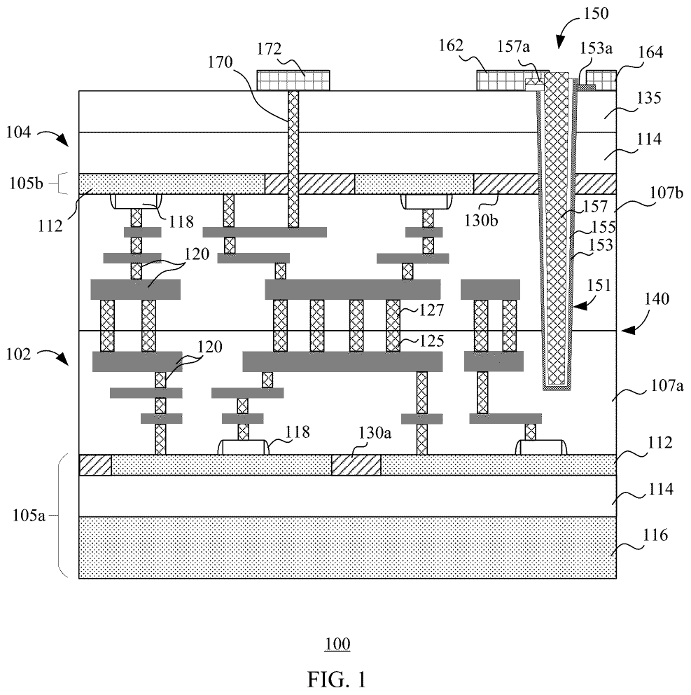

FIG. 1 illustrates a cross-sectional view of an embodiment of a structure 100. The structure 100 may be a stacked device. The structure 100 includes a chip 102 and a chip 104 stacked over and bonded to the chip 102. The chips 102 and 104 may each be part of two different wafers which are stacked and bonded together, and the stacked device may be a bonded wafer stack. Alternatively, the chips 102 and 104 may each be individual chips after wafer singulation, and the stacked device may be a bonded chip stack. In yet other embodiments, one of the chips 102 and 104 may be part of a wafer, while the other chip may be an individual chip after wafer singulation, and the chips 102 and 104 may be bonded together, for example, in a chip-to-wafer bonding process.

The chip 102 may include a substrate 105a and a wiring or metallization structure arranged over the substrate 105a. The substrate 105a may be a semiconductor substrate, such as a crystal-on-insulator (COI) (e.g., silicon-on-insulator (SOI)) substrate. The substrate 105a may include a device or active layer 112, an insulator layer 114 and a base layer 116. For example, the active layer 112 and the base layer 116 may be formed of a semiconductor material, such as silicon, silicon germanium, germanium, and the insulator layer 114 may be formed of a dielectric material such as silicon oxide. Other types of substrates, such as a bulk semiconductor substrate may also be used. Device isolation regions 130a may be arranged in the substrate 105a. The device isolation regions 130a, for example, may be shallow trench isolation regions. In some embodiments, the device isolation regions 130a and the active layer 112 of substrate 105a may have the same thickness. The device isolation regions 130a may isolate portions of the active layer 112. In some embodiments, a first surface of the device isolation regions 130a may abut a dielectric 107a, while a second surface opposite to the first surface of the device isolation regions 130a may abut the insulator layer 114. The first surface, for example, may be a top surface of the device isolation regions 130a, while the second surface may be a bottom surface of the device isolation regions 130a. Electronic components 118, including active components, may be formed on the substrate 105a. For example, the active components may include transistors arranged on the active layer 112. The gate electrodes of the transistors may be arranged on the active layer 112 with the source and drain regions of the transistor arranged in the active layer 112. It is understood that there may be a plurality of electronic components and different types of electronic components on the substrate 105a. The metallization structure may include the dielectric 107a and interconnects 120 disposed in the dielectric 107a. The interconnects 120 may include metal layers and via contacts for connecting the electronic components 118 to perform the desired functions. The metal layers may be arranged in a plurality of metal levels (e.g., M₁ to Mₓ) and the via contacts may interconnect the metal layers of the metal levels. The chip 102 may further include bonding pads or vias 125 arranged over a top surface of the interconnects 120 (e.g., on the uppermost metal layer in metal level Mₓ of the interconnects 120).

The chip 104 may include a substrate 105b and a metallization structure. Electronic components 118, such as active components, may be formed on the substrate 105b. As illustrated in FIG. 1, the chip 104 may be in a flipped orientation when stacked over the chip 102. Similar to the metallization structure of chip 102, the metallization structure of chip 104 may include a dielectric 107b and interconnects 120 disposed in the dielectric 107b. The dielectric 107b may be arranged over the dielectric 107a of chip 102 in the device stack. Although the dielectric 107a of chip 102 and the dielectric 107b of chip 104 are each illustrated as a single layer, it is understood that dielectric 107a and dielectric 107b may be formed of multiple layers of dielectric material in a back-end-of-line (BEOL) process. The dielectric 107a and the dielectric 107b may be formed of layers of dielectric material, such as silicon oxide, silicon nitride, low-k dielectric (e.g., SiCOH). The chip 104 may further include bonding pads or vias 127 arranged over a top surface of the interconnects 120 (e.g., on the uppermost metal layer of the interconnects 120) of chip 104. The interconnects 120 and bonding pads or vias 125 or 127 may be formed of a metallic material such as copper, copper alloy, aluminum or a combination thereof. Other suitable types of metal, alloys or conductive materials may also be useful. The substrate 105b may be arranged over the dielectric 107b in the device stack. The substrate 105b may include a device or active layer 112 on which one or more of the active components may be formed. Device isolation regions 130b may be arranged in the substrate 105b. The device isolation regions 130b, for example, may be shallow trench isolation regions. In some embodiments, the device isolation regions 130b and the active layer 112 of substrate 105b may have the same thickness. The device isolation regions 130b may isolate portions of the active layer 112. The device isolation regions 130a and 130b may each be formed of a dielectric material such as silicon oxide. The chip 104 may further include an insulator layer 114 over the active layer 112. In some embodiments, a first surface of the device isolation regions 130b may abut the dielectric 107b, while a second surface opposite to the first surface of the device isolation regions 130b may abut the insulator layer 114. The first surface, for example, may be a top surface of the device isolation regions 130b, while the second surface may be a bottom surface of the device isolation regions 130b.

The chip 104 may be bonded to the chip 102 at a bonding interface 140, forming the device stack. The device stack may be a three-dimensional (3D) structure formed by stacking the chips or wafers vertically. The dielectric 107b of chip 104 may directly contact or abut the dielectric 107a of chip 102 at the bonding interface 140. The bonding vias 127 of chip 104 may directly contact or abut the bonding vias 125 of chip 102 at the bonding interface 140. The interconnects 120 of chip 102 may be interconnected to the interconnects 120 of chip 104 through the bonding vias 125 and 127. The interconnects 120 of chip 102 and chip 104 may couple one or more of the electronic components 118 of chip 102 to one or more of the electronic components 118 of chip 104. The bonding vias 125 of chip 102 may have a width which is wider at the bonding interface 140 and tapers to a smaller width in a direction into the dielectric 107a and away from the bonding interface 140 (not shown). Similarly, the bonding vias 127 of chip 104 may have a width which is wider at the bonding interface 140 and tapers to a smaller width in a direction into the dielectric 107b and away from the bonding interface 140 (not shown). As illustrated, the device stack may include the interconnects 120 arranged vertically between two active layers (e.g., the active layer 112 of chip 102 and the active layer 112 of chip 104).

A device stack dielectric or capping layer 135 may be arranged over the chip 104. In one embodiment, the capping layer 135 may be arranged over the insulator layer 114. In other embodiments, the insulator layer 114 need not be provided, and instead the capping layer 135 may be arranged directly over the active layer 112 of substrate 105b. In the case that the insulator layer 114 is not provided, the first surface of the device isolation regions 130b may abut the dielectric 107b, while the second surface opposite to the first surface of the device isolation regions 130b may abut the capping layer 135. The capping layer 135 may be formed of a dielectric material such as silicon oxide.

A trench capacitor 150 may be arranged in the device stack. As shown in FIG. 1, the trench capacitor 150 may extend through the chip 104, the bonding interface 140 and at least partially into the chip 102. The trench capacitor 150 may extend completely through a depth (or thickness) of the chip 104. As illustrated in FIG. 1, the trench capacitor 150 may extend completely through a thickness of the dielectric 107b of chip 104 and into a portion of the dielectric 107a of chip 102. In one embodiment, the trench capacitor 150 may extend only through a portion of the dielectric 107a of the chip 102. For example, the trench capacitor 150 does not extend completely through a depth or thickness of the dielectric 107a. In another example, the trench capacitor 150 may have an upper portion through the entire thickness of the dielectric 107b of chip 104, and a lower portion extending partially through a thickness of the dielectric 107a of chip 102. The trench capacitor 150 may further extend through the device isolation region 130b, the insulator layer 114 of chip 104 and the capping layer 135 to a top surface of the capping layer 135. Accordingly, the trench capacitor 150 may extend from a top side of the device stack through the dielectric 107b of the chip 104 and partially into the dielectric 107a of the chip 102. In some embodiments, the trench capacitor 150 may be arranged above a transistor of the lower chip (e.g., chip 102) of the device stack. The trench capacitor 150, for example, may overlap a gate electrode of the transistor.

The trench capacitor 150 may include a trench opening 151 and a capacitor stack in the trench opening 151. In one embodiment, the trench capacitor 150 may include a first electrode 153 lining sidewalls and a bottom surface of the trench opening 151, a capacitor dielectric 155 arranged over and lining the first electrode 153 and a second electrode 157 arranged over the capacitor dielectric 155. The capacitor dielectric 155 may be conformal to the first electrode 153 in the trench opening 151, and the second electrode 157 may fill a remaining space in the trench opening 151. In some embodiments, a seed or liner layer (not shown) may be arranged to line the trench opening 151 and the first electrode 153 may be arranged conformally over the seed layer in the trench opening 151. In one embodiment, the first electrode 153 may include an edge portion 153a extending external to the trench opening 151 and over a surface of the capping layer 135 for connection to a metal layer 164. In one embodiment, the second electrode 157 may include an edge portion 157a extending external to the trench opening 151 and over a surface of the capping layer 135 for connection to a metal layer 162. The metal layers 162 and 164 may be arranged over the top side of the device stack. The metal layer 162 may contact the edge portion 157a of the second electrode 157 of the capacitor stack and the metal layer 164 may contact the edge portion 153a of the first electrode 153 of the capacitor stack. The seed layer and the first electrode 153 may be formed of a conductive material such as copper. The second electrode 157 may be formed of a conductive material such as doped polysilicon or copper. The capacitor dielectric 155 may be formed of a dielectric material such as silicon oxide, silicon nitride, or silicon oxynitride.

The trench capacitor 150 may be a 3D capacitor, which is vertically oriented in the device stack so that the trench capacitor 150 extends in a vertical direction with respect to the substrate of the lower chip in the device stack. For example, the trench capacitor 150 may be arranged perpendicular to a lateral surface of the substrate of the lower chip in the device stack, such as substrate 105a of chip 102. The trench capacitor 150, for example, may have a depth of about 13 um to about 16 um in the device stack. In one embodiment, the trench capacitor 150 may have a depth of about 15 um to about 16 um in the device stack. Other depths for the trench capacitor 150 may also be used depending on the devices or application of the device stack.

In one embodiment, a through via 170 may extend through a device isolation region 130b and the capping layer 135. The through via 170 may couple the interconnects 120 to an interconnection 172. The interconnection 172, for example, may be a metal layer arranged over the capping layer 135. The through via 170 and the metal layer (interconnection 172) may be formed of a metallic material, such as, Cu.

As described, various embodiments provide a deep trench capacitor in a device stack having at least two chips stacked and bonded together. The trench capacitor may be vertically integrated in the stacked chips. Accordingly, various embodiments may advantageously integrate the capacitor structure with a high aspect ratio to obtain a high capacitance density (e.g., 40 nF/mm²) in the device stack while using a small chip/circuit area (e.g., horizontal chip area) compared to capacitor structures in conventional semiconductor devices. The trench capacitor may use a small percentage of the chip footprint/area in the device stack and leave the remaining chip area for other devices. Further, the capacitor structure according to various embodiments may be integrated with increased capacitance density in a stacked structure which is integrated with at least two interfaces for forming electronic components (e.g., active layer 112 of chip 102 and active layer 112 of chip 104), while retaining a small chip footprint. The respective active layers 112 of the two bonded chips 102 and 104 may be located near the front side and back side of the device stack.

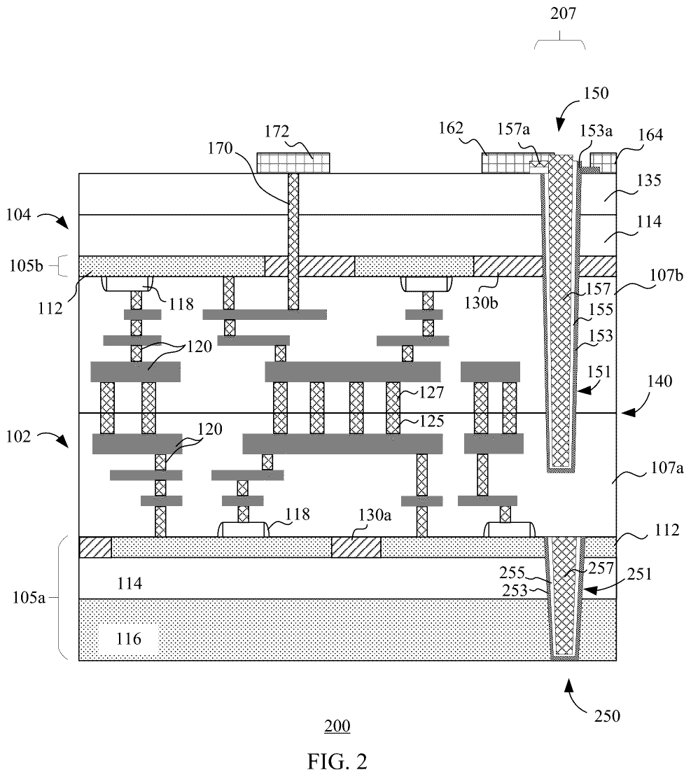

FIG. 2 illustrates a cross-sectional view of an embodiment of a structure 200. Referring to FIG. 2, the structure 200 may be similar to the structure 100 in FIG. 1, but may include a second trench capacitor 250 arranged in the substrate 105a of chip 102. The second trench capacitor 250, for example, may be formed in a front end process during fabrication of the chip 102 and prior to stacking and bonding of the chips 102 and 104. In one embodiment, the second trench capacitor 250 may be arranged below the trench capacitor 150 in the device stack. For example, the trench capacitor 150 may be a top trench capacitor while the second trench capacitor 250 may be a bottom trench capacitor in a capacitor region 207 of the device stack. The second trench capacitor 250 may include a trench opening 251 and a capacitor stack in the trench opening 251. In one embodiment, the second trench capacitor 250 may include a first electrode 253 lining the trench opening 251, a capacitor dielectric 255 arranged over and lining the first electrode 253 and a second electrode 257 arranged over the capacitor dielectric 255. The second electrode 257 may fill a remaining space in the trench opening 251. In some embodiments, a liner layer (not shown) may be arranged to line the trench opening 251 and the first electrode 253 may be arranged conformally over the liner layer in the trench opening 251. The first electrode 253 and the second electrode 257 may be coupled through the interconnects 120 of the metallization structure. For example, the first electrode 253 may include an edge portion extending external to the trench opening 251 and over a surface of the active layer 112 of substrate 105a (not shown), which may be coupled through the interconnects 120 (e.g., through contact landing on the edge portion of the first electrode 253). The second electrode 257, for example, may include an edge portion extending external to the trench opening 251 and over a surface of the active layer 112 of substrate 105a (not shown), which may be coupled through the interconnects 120 (e.g., through contact landing on the edge portion of the second electrode 257). In some embodiments, the first electrode 253 and/or the second electrode 257 may be coupled through a conductive structure arranged on the substrate 105a. The conductive structure, for example, may be formed of polysilicon. Providing the second trench capacitor 250 in addition to the trench capacitor 150 in the device stack may advantageously double the capacitance density of the capacitor structure in the device stack, while requiring a smaller dedicated chip/circuit area in the device stack compared to capacitor structures in conventional semiconductor devices. The dedicated area for a capacitor structure with the desired capacitance density in the device stack may accordingly be further reduced compared to the chip area used for capacitor structures in conventional semiconductor devices.

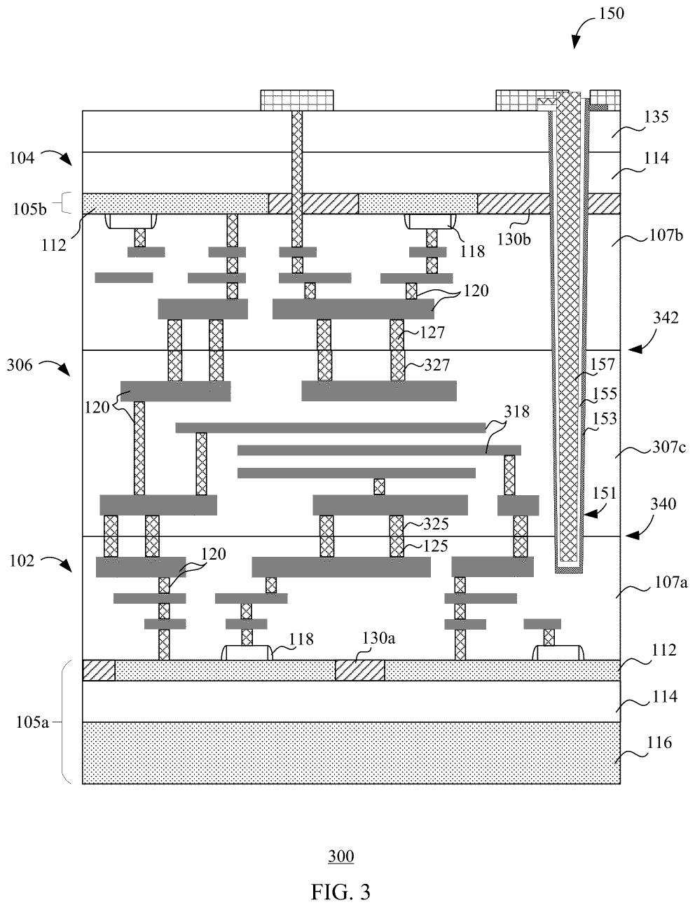

FIG. 3 illustrates a cross-sectional view of an embodiment of a structure 300. Referring to FIG. 3, the structure 300 may be similar to the structure 100 in FIG. 1, but may have more than two chips stacked together to form the device stack. The structure 300 includes chip 102, chip 104 and chip 306 stacked one over another. Chip 306, for example, may be arranged between chips 102 and 104. The chip 306 may be stacked over and bonded to the chip 102 at a bonding interface 340 in a first bonding process, and the chip 104 may be stacked over and bonded to the chip 306 at a second bonding interface 342 in a second bonding process to form the device stack. The chip 306 may be in a flipped orientation when stacked over the chip 102. The chip 104 may be in a flipped orientation when stacked over the chip 306. The chip 306 may include a metallization structure. Similar to the metallization structure of chip 102 and chip 104, the metallization structure of chip 306 may include a dielectric 307c and interconnects 120 disposed in the dielectric 307c. The dielectric 307c may be arranged over the dielectric 107a of chip 102 in the device stack. Although the dielectric 307c of chip 306 is illustrated as a single layer, it is understood that dielectric 307c may be formed of multiple layers of dielectric material in a BEOL process. For example, the dielectric 307c may be formed of layers of dielectric material, such as silicon oxide, silicon nitride, low-k dielectric (e.g., SiCOH). The chip 306 may further include bonding pads or vias 325 and 327 arranged over a top surface and a bottom surface of the interconnects 120, respectively (e.g., on the uppermost metal layer and on the bottommost metal layer of the interconnects 120). The interconnects 120 and bonding pads or vias 325 and 327 may be formed of a metallic material such as copper, copper alloy, aluminum or a combination thereof. Other suitable types of metal, alloys or conductive materials may also be useful. One or more electronic components 318 may be arranged in the dielectric 307c of the metallization structure of chip 306. In one embodiment, the electronic component(s) 318 may include a metal-insulator-metal (MIM) capacitor arranged in the dielectric 307c. The MIM capacitor, for example, may have a planar configuration (e.g., 2D orientation) in chip 306. For example, the MIM capacitor may be arranged such that it is parallel to the lateral surface of the substrate of the lower chip in the device stack, such as substrate 105a of chip 102. In some embodiments, the chip 306 may be provided without an active layer. The dielectric 107b of chip 104 may be arranged over the dielectric 307c of chip 306, and the substrate 105b, including active layer 112 of chip 104, may be arranged over the dielectric 107b. Similarly, capping layer 135 may be arranged over the chip 104.

In one embodiment, the bonding vias 325 may be formed over the interconnects 120, such as on the uppermost metal layer (e.g., in metal level Mₓ) of chip 306, before stacking and bonding chip 306 to chip 102. The chip 306 may then be inverted, stacked over the chip 102 and bonded to the chip 102. As for the bonding vias 327, it may be formed over the interconnects 120 after stacking and bonding chip 306 to chip 102, such as on the bottommost metal layer (e.g., in metal level M₁) of chip 306. The interconnects 120 of chip 306 may be interconnected to the interconnects 120 of chip 102 through the bonding vias 125 and 325, and to the interconnects 120 of chip 104 through the bonding vias 127 and 327. The bonding vias 125 of chip 102 may have a width which is wider at the bonding interface 340 and tapers to a smaller width in a direction into the dielectric 107a and away from the bonding interface 340. The bonding vias 325 of chip 302 may have a width which is wider at the bonding interface 340 and tapers to a smaller width in a direction into the dielectric 307c and away from the bonding interface 340. Similarly, the bonding vias 127 of chip 104 may have a width which is wider at the second bonding interface 342 and tapers to a smaller width in a direction into the dielectric 107b and away from the second bonding interface 342. The bonding vias 327 may have a width which is wider at the second bonding interface 342 and tapers to a smaller width in a direction into the dielectric 307c and away from the second bonding interface 342.

In one embodiment, the trench capacitor 150 may extend through the chip 104, the second bonding interface 342, the chip 306, the bonding interface 340 and at least partially into the chip 102. The trench capacitor 150 may extend completely through a depth of the chip 104 and a depth of the chip 306. As illustrated in FIG. 3, the trench capacitor 150 may extend completely through a thickness of the dielectric 107b of chip 104 and a thickness of the dielectric 307c of chip 306 and into a portion of the dielectric 107a of chip 102. In one embodiment, the trench capacitor 150 may extend only through a portion of the dielectric 107a of the chip 102. For example, the trench capacitor 150 does not extend completely through a depth or thickness of the dielectric 107a. In another example, the trench capacitor 150 may have an upper portion through the entire thickness of the dielectric 107b of chip 104 and the entire thickness of the dielectric 307c of chip 306, and a lower portion extending partially through a thickness of the dielectric 107a of chip 102. The trench capacitor 150 may further extend through the device isolation region 130b in chip 104, the insulator layer 114 of chip 104 and the capping layer 135 to a top surface of the capping layer 135. Accordingly, a deeper trench capacitor 150 may be provided when more chips are stacked and bonded together to form the device stack.

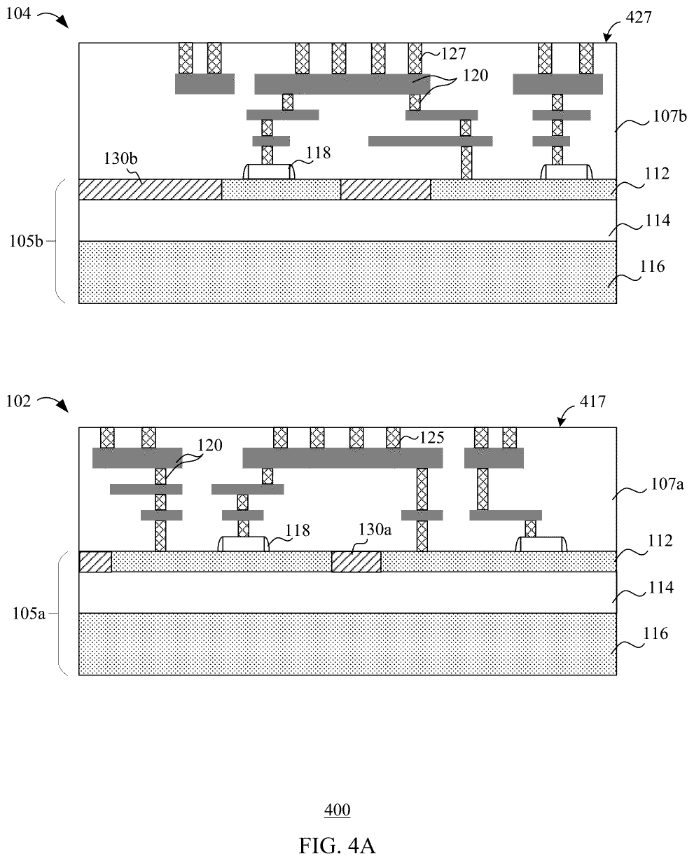

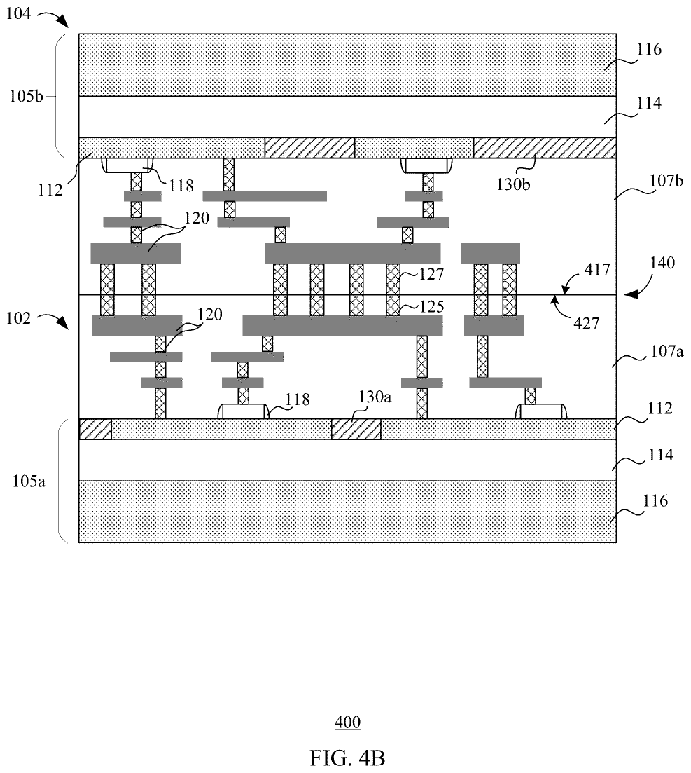

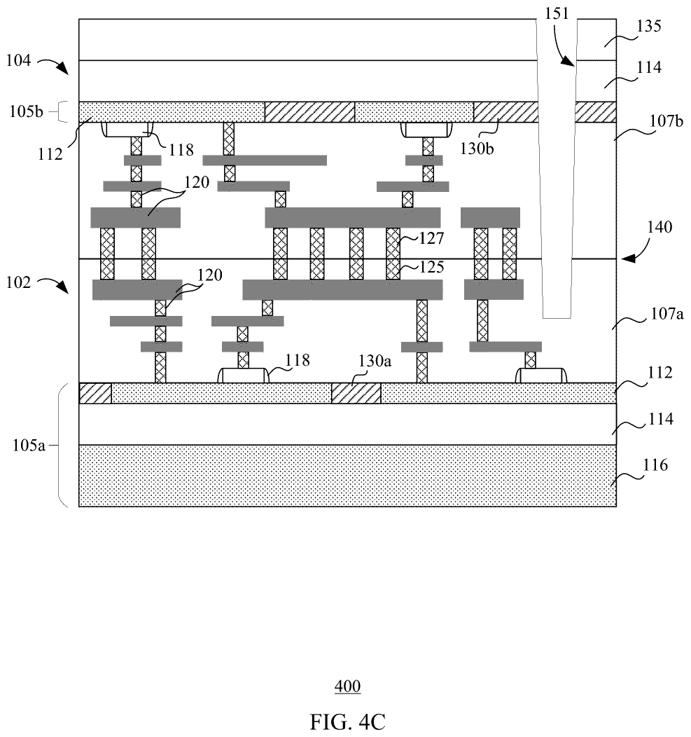

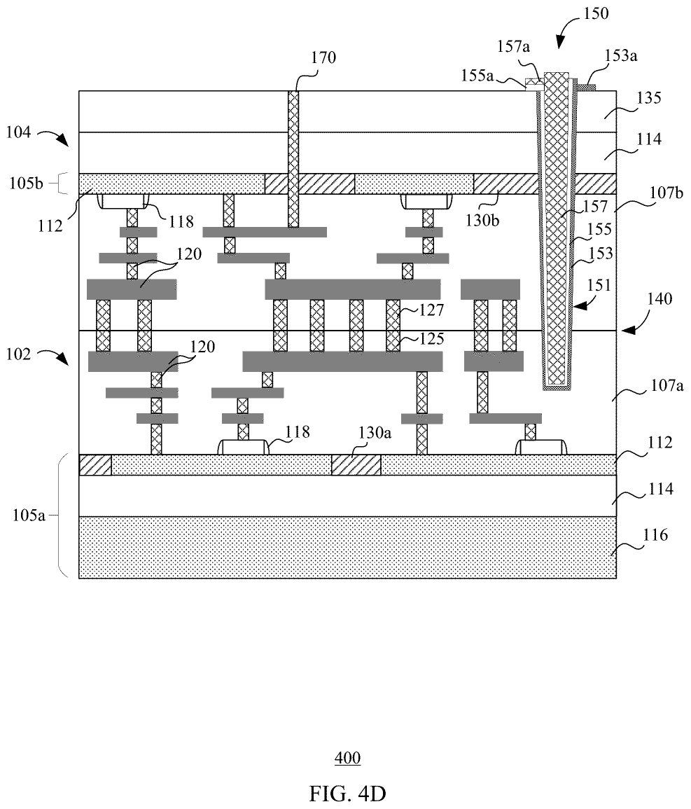

FIGS. 4A-4D show cross-sectional views of a process 400 for forming a structure. The structure, for example, is similar to that described in FIGS. 1-3. As such, common elements may not be described or described in detail.

Referring to FIG. 4A, chips 102 and 104 may be formed. The chips 102 and 104 may be at stage where they have been fully processed. The chip 102 may include electronic components 118 formed on the substrate 105a. The substrate 105a may include active layer 112, insulator layer 114 and base layer 116. In other embodiments, the substrate 105a may be a bulk substrate having the active layer 112. Device isolation regions 130a may be formed in the substrate 105a. In some embodiments, the device isolation regions 130a and the active layer 112 of substrate 105a may have the same thickness. The device isolation regions 130a may isolate portions of the active layer 112. The chip 102 may further include a metallization structure formed over the substrate 105a in a BEOL process. The metallization structure may include the dielectric 107a and interconnects 120 disposed in the dielectric 107a. Bonding pads or vias 125 may be formed on the uppermost metal layer of the interconnects 120. A top surface 417 of the dielectric 107a and the bonding vias 125 may be substantially coplanar. Similarly, the chip 104 may include electronic components 118 formed on the substrate 105b. The substrate 105b may include active layer 112, insulator layer 114 and base layer 116. In other embodiments, the substrate 105b may be a bulk substrate having the active layer 112. Device isolation regions 130b may be formed in the substrate 105b. In some embodiments, the device isolation regions 130b and the active layer 112 of substrate 105b may have the same thickness. The device isolation regions 130b may isolate portions of the active layer 112. At least one device isolation region 130b may be formed at a region of the substrate 105b corresponding to where the trench capacitor will be subsequently formed through the chip 104. The chip 104 may further include a metallization structure formed over the substrate 105b in a BEOL process. The metallization structure may include the dielectric 107b and interconnects 120 disposed in the dielectric 107b. Bonding pads or vias 127 may be formed on the uppermost metal layer of the interconnects 120. A top surface 427 of the dielectric 107b and the bonding vias 127 may be substantially coplanar.

The chips 102 and 104 may be joined together in a face-to-face bonding. Referring to FIG. 4B, the chip 104 may be flipped such that the fronts of the chips 102 and 104 are facing one another. The chips 102 and 104 may be aligned and the chip 104 may be stacked over chip 102 with the dielectric 107b of chip 104 facing the dielectric 107a of chip 102, forming the device stack. The chips 102 and 104, for example, may be bonded together via wafer bonding processes. In other embodiments, the chips 102 and 104 may be bonded together via chip-to-wafer or chip-to-chip bonding processes. The chips 102 and 104 may be bonded together at the bonding interface 140. The top surface 417 of dielectric 107a of chip 102 may directly contact the top surface 427 of the dielectric 107b of chip 104. A top surface of the bonding vias 125 may directly contact a top surface of the corresponding bonding vias 127. In one embodiment, the chips 102 and 104 may be bonded together via hybrid bonding. For example, metal-metal bonds (e.g., Cu—Cu bonds) may be formed between the bonding vias 125 of chip 102 and the corresponding bonding vias 127 of chip 104, and dielectric-dielectric bonds (e.g., oxide-oxide bonds) may be formed between the dielectric 107a of chip 102 and the dielectric 107b of chip 104. For example, standard thermocompressive bonding tools and techniques may be used. After bonding, thinning of the upper chip (e.g., chip 104) of the device stack may be performed. A thickness of the substrate of the upper chip of the device stack may be reduced. The chip 104 may be backgrinded such that the base layer 116 of the substrate 105b is removed. In the case that the substrate 105b of chip 104 is a bulk substrate, the substrate 105b may be backgrinded until a bottom surface of the device isolation regions 130b is exposed. The capping layer 135 may then be deposited over the upper chip (e.g. chip 104).

Referring to FIGS. 4C-4D, a trench capacitor may be formed in the device stack. The trench capacitor may be formed to extend through the chip 104 and at least partially into the chip 102. A trench opening 151 may be formed through the chip 104, the bonding interface 140 and at least partially into the chip 102. As illustrated in FIG. 4C, the trench opening 151 may be formed from a top side of the device stack (e.g., top surface of the capping layer 135) through the dielectric 107b of chip 104, the bonding interface 140 and into the dielectric 107a of chip 102. The trench opening 151 may be formed by lithography and etching processes. The trench opening 151 may be etched through the device isolation region 130b of chip 104. In one embodiment, the trench opening 151 may be etched to a lower metal level (e.g., M2 or M3) of the metallization structure of the lower chip (e.g., chip 102) of the stacked structure. The trench opening 151 may be formed with a high aspect ratio (e.g., deep depth and narrow width). The trench opening 151, for example, may have depth of about 13 um to about 16 um from the top side of the device stack (e.g., from the top surface of the capping layer 135). In one embodiment, the trench opening 151, for example, may have depth of about 15 um to about 16 um from the top side of the device stack. The trench opening 151, for example, may be formed with a critical dimension of about 1 um. Other critical dimensions may also be applicable depending on technology or application of the device stack. In some embodiments, the trench opening 151 may be above a transistor and overlap the transistor of the lower chip (e.g., chip 102) of the stacked structure. In other embodiments, the trench opening 151 may be above a second trench capacitor (not shown in FIG. 4C) formed in the substrate of the lower chip (e.g., substrate 105a of chip 102) of the stacked structure. A capacitor stack may be formed in the trench opening 151. The capacitor stack may fill the trench opening 151. Referring to FIG. 4D, a first electrode 153 may be formed to line the trench opening 151, a capacitor dielectric 155 may be formed over the first electrode 153, and a second electrode 157 may be formed over the capacitor dielectric 155. The capacitor dielectric 155 may be conformal to the first electrode 153 in the trench opening 151, and the second electrode 157 may fill a remaining space in the trench opening 151. In some embodiments, a seed layer (not shown) may be formed to line the trench opening 151 and the first electrode 153 may be deposited conformally over the seed layer in the trench opening 151. In one embodiment, the first electrode 153 may include an edge portion 153a extending external to the trench opening 151 and over a surface of the capping layer 135 for connection to an interconnection such as a first metal layer which may be formed over a top side of the device stack. In one embodiment, the second electrode 157 may include an edge portion 157a extending external to the trench opening 151 and over a surface of the capping layer 135 for connection to an interconnection such as a second metal layer which may be formed over a top side of the device stack. In one embodiment, the capacitor dielectric 155 may include an edge portion 155a extending external to the trench opening 151 and over a surface of the capping layer 135. The first electrode 153, capacitor dielectric 155 and second electrode 157 may be formed by depositing its constituent material using deposition techniques, such as chemical vapor deposition, and patterned, for example using lithography and etching processes, to form the edge portion 153a, 155a and 157a.

Through via 170 may be formed to extend through a device isolation region 130b and the capping layer 135. The through via 170 may couple the interconnects 120 to an interconnection, such as a third metal layer subsequently formed over the capping layer 135. The process 400 may continue with forming additional interconnections over the device stack, such as deposition of the first, second and third metal layers.

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

What is claimed is:

1. A structure, comprising:
a first chip including a first dielectric and first interconnects arranged in the first dielectric;
a second chip stacked over and bonded to the first chip at a bonding interface to form a device stack, the second chip including a second dielectric over the first dielectric and second interconnects arranged in the second dielectric; and
a trench capacitor arranged in the device stack, wherein the trench capacitor extends through the second chip, the bonding interface and at least partially into the first chip.

2. The structure of claim 1, wherein the trench capacitor extends completely through a thickness of the second dielectric and into a portion of the first dielectric of the first chip.

3. The structure of claim 1, wherein the first chip further includes a first active layer, the first dielectric is arranged over the first active layer.

4. The structure of claim 3, wherein the second chip further includes a second active layer, the second active layer is arranged over the second dielectric.

5. The structure of claim 4, wherein the second chip further includes a device isolation region isolating a portion of the second active layer, and wherein the trench capacitor extends through the device isolation region.

6. The structure of claim 4, further comprising a capping layer over the second active layer, and wherein the trench capacitor extends through the capping layer to a top surface of the capping layer.

7. The structure of claim 6, wherein the second chip further includes a device isolation region isolating a portion of the second active layer, and further comprising a through via extending through the device isolation region and the capping layer, the through via coupling the second interconnects to an interconnection.

8. The structure of claim 1, further comprising a third chip stacked over and bonded to the second chip at a second bonding interface to form the device stack, the third chip including a third dielectric over the second dielectric and third interconnects arranged in the third dielectric, and wherein the trench capacitor further extends through the third chip and the second bonding interface.

9. The structure of claim 8, wherein the third chip further includes a second active layer, the second active layer is arranged over the third dielectric.

10. The structure of claim 9, wherein the third chip further includes a device isolation region isolating a portion of the second active layer, and wherein the trench capacitor extends through the device isolation region.

11. The structure of claim 1, wherein the trench capacitor comprises a first electrode lining a trench opening, a capacitor dielectric over the first electrode, and a second electrode over the capacitor dielectric.

12. The structure of claim 11, further comprising a first metal layer and a second metal layer arranged over a top side of the device stack, wherein the first electrode of the trench capacitor is connected to the first metal layer, and the second electrode of the trench capacitor is connected to the second metal layer.

13. The structure of claim 1, wherein the second interconnects of the second chip are interconnected to the first interconnects of the first chip through a plurality of bonding vias.

14. The structure of claim 1, wherein the first chip further includes a substrate, the first dielectric is arranged over the substrate, and further comprising a second trench capacitor arranged in the substrate.

15. The structure of claim 14, wherein the second trench capacitor is arranged below the trench capacitor in the device stack.

16. A structure, comprising:
a first chip including a first dielectric over a first active layer and first interconnects arranged in the first dielectric;
a second chip stacked over the first chip to form a device stack, the second chip including a second dielectric over the first dielectric, and a second active layer over the second dielectric, wherein second interconnects are arranged in the second dielectric; and
a trench capacitor extending from a top side of the device stack through the second dielectric of the second chip and at least partially into the first dielectric of the first chip.

17. The structure of claim 16, wherein the trench capacitor comprises a trench opening extending from the top side of the device stack through the second dielectric of the second chip and at least partially into the first dielectric of the first chip, and a capacitor stack arranged in the trench opening.

18. The structure of claim 17, wherein the capacitor stack comprises a first electrode lining the trench opening, a capacitor dielectric over the first electrode, and a second electrode over the capacitor dielectric.

19. A method of forming a structure, comprising:
forming a first chip including a first dielectric and first interconnects arranged in the first dielectric and a second chip including a second dielectric and second interconnects arranged in the second dielectric;
stacking the second chip over the first chip with the second dielectric facing the first dielectric to form a device stack;
bonding the first chip and the second chip together; and
forming a trench capacitor in the device stack, wherein the trench capacitor extends through the second chip and at least partially into the first chip.

20. The method of claim 19, wherein forming the trench capacitor comprises forming a trench opening through the second chip and at least partially into the first chip, and forming a capacitor stack in the trench opening.
